(19) United States
(12) Patent Application Publication
(10) Pub. No.: US 2006/0014378 A1
(43) Pub. Date: Jan. 19, 2006

(54) System and method to form improved seed layer

(76) Inventors: Sanjeev Aggarwal, Plano, TX (US); Kelly J. Taylor, Allen, TX (US); Asad Haider, Plano, TX (US); Alfred J. Griffin JR., Dallas, TX (US)

Correspondence Address: TEXAS INSTRUMENTS INCORPORATED, P O BOX 655474, M/S 3999, DALLAS, TX, 75265, US

(21) Appl. No.: 10/890,663

(22) Filed: Jul. 14, 2004

(51) Int. Cl. H01L 21/4763; H01L 21/44

(52) U.S. Cl. 438/628

(57) ABSTRACT

A method is disclosed to form a seed layer for an integrated circuit. The method may include depositing a metal seed layer (106) over a barrier layer (104) such that the metal seed layer (106) has a greater thickness along a top surface portion (114) of at least one recessed feature (102) formed in the substrate that is substantially coplanar with the substrate than a sidewall surface portion (112) of the at least one recessed feature (102). A portion of the metal seed layer (106) is etched from the top surface portion (114) of the at least one recessed feature (102) to improve coverage of the metal seed layer (106) along the sidewall surface portion (112) of the at least one recessed feature (102) and to mitigate overhang of the metal seed layer.

### TECHNICAL FIELD

This invention relates to integrated circuits, and more specifically relates to a system and method to form an improved seed layer.

### BACKGROUND

Electrochemical deposition (ECD) or electroplating is a deposition method that can be used for copper metallization including in semiconductor manufacturing. Typically, the ECD process is implemented over a corresponding metal seed layer, such as copper. Since copper, as well as other desirable mobile conductive materials, have high diffusivities and readily diffuse into dielectric layer, a corresponding barrier layer is employed to mitigate diffusion of copper or other seed layer into the dielectric material. Examples of diffusion barrier layer materials include tantalum, tantalum nitride, platinum, cobalt, molybdenum and titanium tungsten or other barrier metals (e.g., refractory materials, such as elemental refractory metals, as well as compounds and alloys thereof) that are employed in semiconductor manufacturing. The diffusion barrier layer typically is a thin layer (e.g., about 75 Å) so as not affect the resistivity of a high aspect ratio plug while still acting as a barrier metal.

Physical vapor deposition (PVD) encompasses a broad range of metallization techniques that can be utilized to form a corresponding seed layer, such as for use in single and dual damascene structures. However, as dimensions of trenches and vias in semiconductor devices continue to decrease in size, many existing techniques for PVD metallization can result in a significant amount of overhang at the opening of trenches and vias. The overhang generally results from the deposition of the barrier and seed layers using conventional RF sputtering techniques. For instance, as a consequence of overhang, asymmetric coverage can occur on edges or the trenches and vias can get pinched at the top. This further can contribute to the occurrence of voids in the vias in a subsequent electroplating process, as the overhang of the barrier and/or seed layers can inhibit filling the vias and trenches.

By way of example, FIG. 1 depicts a semiconductor device at an intermediate fabrication stage. The semiconductor device 10 includes a semiconductor substrate 12 that includes one or more trenches/vias 14 formed therein. A thin barrier layer 16 has been formed over the semiconductor substrate including the trenches/vias 14. The barrier layer typically is formed for a metal that provides good diffuision barrier properties and high electrical conductivity with low ohmic contact resistance. Additionally, the barrier layer 16 should provide good adhesion between the semiconductor substrate 12 and the subsequently applied seed layer 18. The seed layer 18 is applied over the barrier layer 16 and is substantially thicker than the barrier layer.

In the example of FIG. 1, the seed layer 18 has been deposited in a manner that leads to a significant amount of overhang, indicated at 20. The overhang 20 is a consequence of many traditional physical vapor deposition processes due to the asymmetric coverage that can occur during the deposition. The occurrence of overhang can also reduce the coverage of the seed layer along the sidewall portions of the respective trenches and vias 14. As a consequence of the overhang 20, a subsequent electroplating or electro filling process can result in the occurrence of voids in the respective trenches and vias 14.

### SUMMARY

One aspect of the present invention relates to a method to form a seed layer for an integrated circuit. The method includes depositing a metal seed layer over a barrier layer such that the metal seed layer has a greater thickness along a top surface portion of at least one recessed feature formed in the substrate that is substantially coplanar with the substrate than a sidewall surface portion of the at least one recessed feature. A portion of the metal seed layer is etched (e.g., by resputtering) from the top surface portion of the at least one recessed feature. The etching results in improved coverage of the metal seed layer along the sidewall surface portion of the at least one recessed feature as well as mitigates overhang of the metal seed layer. An optional additional deposition phase can also be implemented to further enhance coverage of the seed layer.

Another aspect of the present invention relates to a system for forming a seed layer on a substrate. The system includes a metal target and a first power source coupled to energize the target. A chuck with a power source coupled is positioned below the target for supporting the substrate, and a coil with a RF and DC power source is disposed about a periphery of the chuck. A controller operates to control power applied to the metal target and to the chuck supporting the substrate for depositing target atoms from the metal target on to exposed surfaces of the substrate. The controller further operates to control energization of the coil to redistribute deposited target atoms (e.g., by resputtering using the RF source) and to deposit coil atoms (using the DC source) to improve coverage of the seed layer on sidewalls of at least one of vias and trenches formed in the substrate.

### BRIEF DESCRIPTION OF THE DRAWINGS

FIG. 1 depicts an example of an intermediate stage of a conventional fabrication process manifesting overhang of a seed layer near vias and trenches.

FIG. 2 depicts a first deposition stage of a fabrication process in accordance with an aspect of the present invention.

FIG. 3 depicts a radio frequency resputtering stage that can be employed in a fabrication process in accordance with an aspect of the present invention.

FIG. 4 depicts a second deposition stage that can be employed in a fabrication process in accordance with an aspect of the present invention.

FIG. 5 depicts a metal fill layer applied over a seed layer in accordance with an aspect of the present invention.

FIG. 6 depicts a system for fabricating a semiconductor device in accordance with an aspect of the present invention.

### DETAILED DESCRIPTION

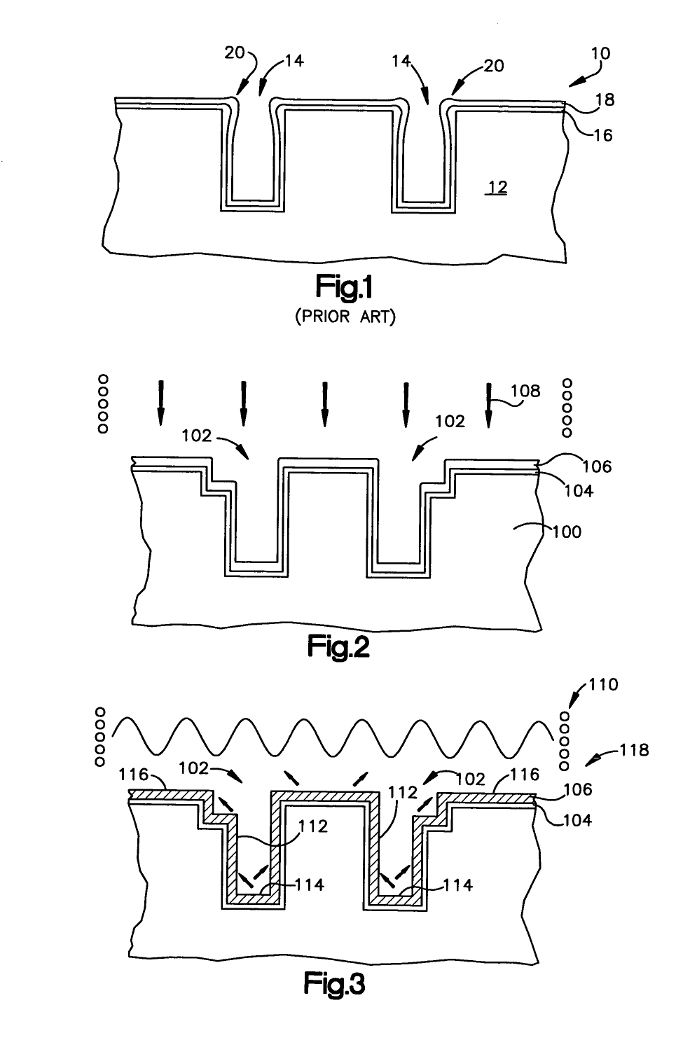

FIGS. 2-5 depict an example of a portion of a semiconductor fabrication process that can be implemented to fabricate a semiconductor device in accordance with an aspect of the present invention. The process affords a reduction in overhang of a seed layer as well as facilitates deposition along the sidewalls of vias and trenches.

FIG. 2 depicts a semiconductor substrate 100 at an intermediate stage of fabrication in which corresponding trenches and vias 102 have been formed in the substrate. The substrate 100, for example, can be silicon dioxide or other semiconductor material providing an interlayer dielectric (ILD). For instance, the trenches and vias 102 can be formed in the semiconductor substrate 100 during a series of etching, patterning and deposition steps, as is known in the art.

A barrier layer 104 is formed over the exposed surfaces of the pattern and etched substrate material 100. The barrier layer 104 can include any suitable barrier metal, which can be selected according to a seed layer 106 that is formed over the barrier layer and according to the type of substrate material. For instance, the material for the barrier layer 104 can be selected to have one or more of the following properties: to prevent diffusion of the seed layer, to provide low film resistivity, to provide good adhesion to both the dielectric material and the seed layer 106, to have high electrical conductivity and relatively low ohmic contact resistance. Examples of common barrier metals include titanium, tungsten, molybdenum, cobalt and platinum to name a few. Additionally, for the particular use of a copper seed layer, according to an aspect of the present invention, suitable barrier metals can include tantalum, tantalum nitride and tantalum silicon nitride.

The seed layer 106 is deposited over the barrier layer 104 according to a physical vapor deposition (PVD) process. The PVD processes can include, for example, evaporation or sputtering. For purposes of simplicity of explanation, the following example is described with respect to implementing the PVD process by sputtering. For the example of sputtering, a metal target (not shown) can be energized in an ionized atmosphere to cause charged atoms to dislodge from the target and migrate towards the substrate 100. The target material can be selected to provide desired seed layer properties, such as a substantially pure metal (e.g., having a purity level of about 99.99%) material or composite metal material. Examples of target materials include titanium and copper.

During the sputtering process, the migrating target atoms deposit on the substrate over the barrier layer 104. By way of further example, the internal environment of the processing chamber can employ ionized argon (Ar) gas that is energized into a plasma. Argon, for example, is often utilized as a sputtering ion species because it is relatively heavy and is a chemically inert gas, which keeps it from reacting with growing film or with the target. Typically, the migrating target atoms are dislodged from the target by exciting gaseous ions (e.g., positive argon ions) in a plasma environment. The gas can be provided into the chamber from a gas source. As the incident ions strike the target, ejected target atoms can travel toward and deposit on exposed surfaces of the substrate 100. The charged plasma environment is created by creating an electric field potential between the target and the substrate 100.

The migration of the target atoms to form the seed layer can also be influenced, such as by creating an electromagnetic field with one or more magnets disposed about the processing chamber. Excess materials within the chamber can be removed from the processing chamber, such as exhausted by a vacuum pump.

A typical sputtering process tends to result in an increased thickness near the center of the substrate 100 relative to portions of the substrate near the periphery thereof. This is because there is usually an increased incidence of target atoms landing on the substrate 100 near its center relative to near its periphery. Additionally, the migration of the target atoms towards the substrate 100 often results in a greater concentration of target atoms depositing on surfaces extending in a plane that is transverse to the direction of travel of the migrating atoms. This results in less seed material being deposited on the sidewalls of the trenches and vias 102 when compared relative to other surfaces of the substrate 100. In some cases, portions of the sidewall may even include no seed layer.

FIG. 3 depicts another part of the fabrication process according to an aspect of the present invention. In FIG. 3, a coil, indicated at 110, substantially surrounds the substrate 100. The coil can be energized to facilitate deposition of the seed layer along the sidewalls 112 of the respective trenches and vias 102. That is, the biasing of the coil 110 at an RF frequency, such as in the range of 100 KHz to about 50 MHz (e.g., approximately 13.56 MHz), operates to excite the plasma within the chamber and cause excited gaseous ions (e.g., argon) to move in a direction towards generally planar transverse surfaces within the vias and trenches 102, as well as transverse top surfaces 116 of the seed layer 106. The energized ion atoms (e.g., argon ions) operate to etch the respective top surfaces 114 and 116. The amount of etching can be controlled to etch a desired thickness of the seed layer 106, such as from approximately one-half to of the entire thickness of the seed layer 106 at the exposed top surfaces 114 and 116. In the case where substantially the entire layer 116 is etched away, this step can be followed by a relatively short step of sputtering where power is applied to the target and chuck, but no power is applied to the coil. Those skilled in the art will understand and appreciated how to optimize the powers to the coil, target and chuck to achieve desired step coverage. The etching further operates within the respective vias and trenches 102 to redistribute or resputter the seed material from the surfaces 114 to redeposit onto the respective sidewalls 112 thereof. The resulting semiconductor structure 118 thus exhibits improved coverage of the seed layer along the respective sidewalls 112 of the vias and trenches 102. The RF biasing of the coil can also result in etching of overhanging portion of the seed layer 106, which might form around the trenches and vias 102. The etching of the overhang around the trenches and vias further can operate to redeposit portions of the seed layer along the sidewalls 112.

Target atoms may deposit on and build up on the coils 110 during sputtering. Accordingly, to mitigate the incidence of other species landing on the substrate 100, the coil 110 can be formed of the same material as the target. To help withstand temperatures and increase coil lifetime, an alloy of target material can be utilized. Additionally, by employing the coil 110 formed of the same material as the target (or an alloy thereof), coil atoms dislodged from the coil during sputtering may augment the seed layer deposition, including at locations near the periphery of the substrate 100.

Those skilled in the art will understand and appreciate that the PVD deposition 108 shown in FIG. 2 for depositing the seed layer 108 can be employed separately from the application of the RF and/or DC energy to the coil 110, as shown in FIG. 3. Alternatively, the PVD process (FIG. 2) can be employed concurrently with energizing the coil with both RF and DC power (FIG. 3), but with the process parameters being controlled so that the deposition of the seed material dominates the combined process to result in formation of the seed layer 106 having a desired thickness.

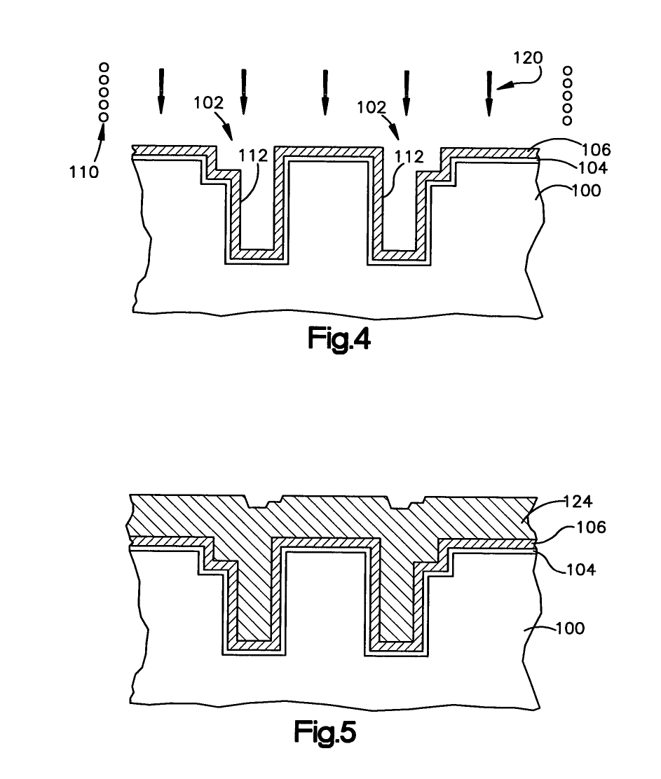

After the RF energy has been applied to the coil 110 to implement the resputtering or etching of the seed layer 106 to enhance the sidewall coverage of the seed layer in the vias and trenches 102, additional deposition of target atoms can be performed, such as by sputtering schematically shown at 120 in FIG. 4. The deposition 120 in FIG. 4 is employed to apply an additional layer of the seed material (e.g., copper). The additional deposition 120 for the seed layer 106 can be implemented as an optional precaution to help ensure that there is adequate coverage of the seed layer over the previously applied barrier layer 104. For example, the PVD deposition from the target can be implemented by applying a DC power to the target in the absence of applying any bias to the chuck that supports the substrate 100. For example, the thickness of the target material applied during the second deposition phase 120 can be approximately 10% the thickness of the initial seed layer 106 deposited according to the PVD process of FIG. 2.

After the seed layer 106 has been deposited, as shown in FIG. 5, electroplating or electrochemical deposition (ECD) can be employed to fill the vias and trenches 102 with an electrically conductive material, indicated at 124. Those skilled in the art will understand and appreciate various electroplating tools that can be utilized to fill the respective vias 102 with a suitable electrically conductive material 124, such as a copper metal, over the seed layer 106. Examples of suitable electroplating equipment are available from vendors such as Novellus Systems Inc. and Applied Materials Inc. Those skilled in the art will understand and appreciate that the electroplating process is facilitated due to the improved deposition of the seed layer along the vias including the sidewalls of the vias. For instance, since overhang can be mitigated as a result of the etching process associated with the application of RF energy to the coils 110, (see e.g., FIG. 3), there is a decreased likelihood of voids developing in the vias during the fill. Typically, voids would initiate where there is a gap in the sidewall seed coverage.

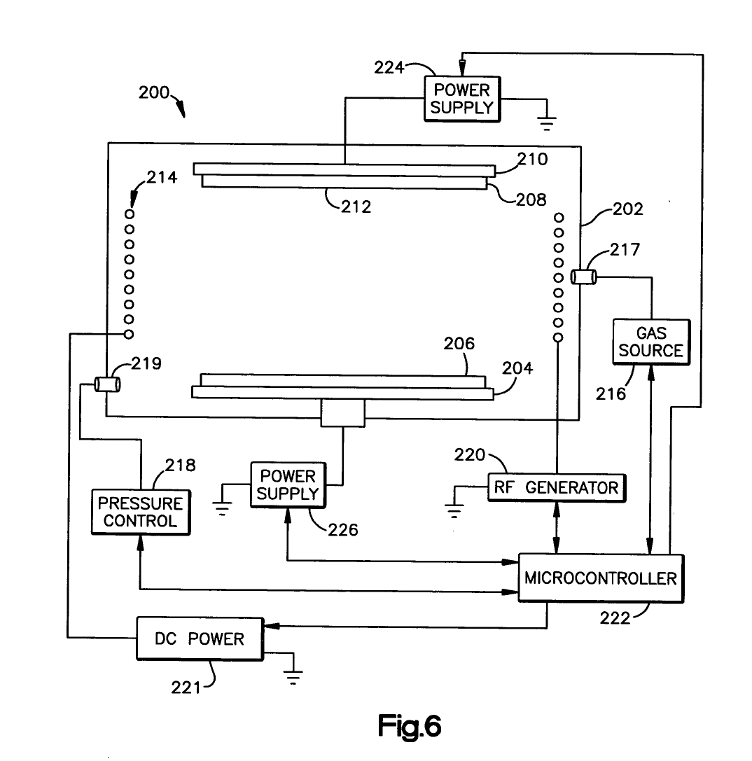

FIG. 6 depicts an example of a system 200 that can be utilized for fabrication of a semiconductor device according to an aspect of the present invention. The system 200 includes a processing chamber 202. The chamber 202 includes a chuck 204 dimensioned and configured for supporting one or more substrates 206. The substrate 206 typically includes a plurality of vias and/or trenches formed therein by traditional fabrication processes that include patterning, etching and deposition. A target 208 of a seed material, such as copper, is mounted in the chamber 202 in an opposing relationship relative to the substrate 206. For instance, the target 208 can be mounted to an electrode or other supporting device 210 operative to provide power (e.g., DC power) to the target 208. In the example of FIG. 6, the target 208 is depicted as having a substantially flat, planar surface 212 facing the substrate 206.

One or more coils 214 are also mounted within the chamber for creating a RF electromagnetic field within the chamber 202. The coil 214 can be a continuous loop surrounding the chuck 204 and the substrate 206. Alternatively, the coil can be configured to substantially surround the chuck 204 and substrate 206, although be a non-continuous loop so that appropriate biasing can be provided to the respective ends of the coil for providing the desired RF field. In order to energize the coil 214, the system 200 also includes an RF generator 220. The RF generator 220 is coupled to the coil to apply RF energy at a desired frequency, such as in the range of 100 KHz to 50 MHz (e.g., 13.56 MHz) at a power generally in the range of about 300 watts to about 1500 watts. The coil 214 can also be energized with DC power, such as from a DC power supply 221. The DC power supply 221 is coupled to the coil to apply DC energy, such as at a power generally in the range of about 100 watts to about 1500 watts.

A source 216 of a desired gas, such as argon, can be fluidly connected with the chamber 202 via one or more inlets or nozzles 217 for maintaining a suitable level of the chemically inert gas within the chamber. The gas supplied by the gas source 216 provides a sputtering ion species to facilitate the deposition of the target material 208 onto the substrate 206. That is, during operation, the positively charged argon ions in the plasma are strongly attracted to a negative charge applied to the target. The gaseous ions accelerate and acquire kinetic energy as they pass through the electric field between the target 212 and the substrate 206. Thus, when the argon ions strike the target surface 212, target atoms are dislodged and by transferring momentum. The dislodged target atoms move through the plasma charged environment and deposit onto the wafer 206.

A suitable pressure can also be maintained within the chamber 202 by a pressure control unit 218. The pressure control unit 218, for example, can be fluidly coupled to one or more exhaust openings 219 in the sidewalls of the chamber 202 for removing excess material from the chamber such as by creating a reduce pressure region (e.g., a vacuum). Additionally, the pressure control unit 218 can be controlled to maintain a desired low pressure atmosphere within the chamber 202.

A microcontroller 222 is communicatively coupled to control the RF generator 220 as well as to control the DC power supply 221 during the deposition process, such as described herein. Additional power supplies 224 and 226 are coupled to provide corresponding power. According to one aspect, the power supply 224 provides DC power (e.g., negative DC bias) to the target 208 and the power supply 226 provides AC power to the substrate 206. The power supply 226, for example, provides AC power to the chuck 204 at a power in the range from about 0 Watts to about 1000 Watts. The power supply 224 is configured to provide DC power to the electrode that supports the target 208, such as in a range of about 30 to 45 KWatts. Those skilled in the art will understand and appreciate that other power levels can be utilized to create a desired electromagnetic field between the target 208 and the substrate 206 within the chamber 202.

The microcontroller 222 can be programmed and/or configured to control operation of the respective power supplies 224 and 226, in addition to the RF generator 222, as part of the deposition process. By way of further example, to form a seed layer on the substrate 206, the microcontroller 222 initially (in a first phase) controls the RF generator 222 to be in the OFF condition while the microcontroller controls the power supply 224 to provide DC power to the target 208 and the power supply 226 to provide a desired AC bias to the chuck 204, which can vary between batch processes. Activation of the power supplies 224 and 226 in a suitable ionized gas environment generates a plasma within the chamber (e.g., ionized argon gas plasma), which causes positive Ar ions within the chamber to collide with the negatively charged target 208. The collision by the Ar ions dislodges metal atoms from the target 208, which then migrate toward the substrate 206 due to transfer of momentum from incident Ar ions and the electric field between the substrate and the chuck 204. The metal target atoms, in turn, deposit on the substrate 206, thereby forming the seed layer over the previously formed barrier layer.

The DC power applied to the coil 214 sputters off material from the coil onto the substrate 206. The material on the coil 214 can be material deposited from the target 212 or the coil material itself. Typically, during operation, the coil 214 has a significant amount of material deposited from the target 212, which allows any material to be utilized to provide the coil. For example, the coil could be conditioned by depositing Cu from the target on a Ta coil. During processing, when the RF and DC power are applied to the coil, the re-deposited Cu would be sputtered. The process could be further optimized where Cu is deposited on the coil through a re-conditioning recipe, which can be implemented periodically (e.g., every so many wafers). The reconditioning would allow the benefits of a pure Cu seed without having to deal with the thermal breakdown of a coil made entirely of Cu.

The initial phase of operation can be maintained, for example, to deposit the seed layer with a desired thickness, such as in the range of about 500 to about 1,000 Å. Next, the microcontroller 222 can turn off the power supply 224 (so that no bias is applied to the target 208) and activate the RF generator 220 to energize the coils 214 with the desired power such as in the range of about 300 to about 1,500 watts. The microcontroller 222 can also activate the DC power supply 221 to provide desired DC power to the coil 214 for sputtering material from the coil onto the substrate 206. The frequency of the RF field can be controlled to be at a frequency in the range of about 100 KHz to about 50 MHz, such as at about 13.56 MHz. The energization of the coil 214 by the RF generator 220 and DC power supply 221 collectively operate to implement a resputtering or etching of the seed layer applied to the substrate 206. The microcontroller 222 can be programmed and configured to cause the RF generator 220 to energize the coil 214 so as to etch a desired thickness, such as from about ½ up to the entire thickness of the applied seed layer.

By way of further example, the energization of the coil 214 results in exciting Ar ions within the chamber 202 to dislodge a portion of the metallic atoms that have been deposited on the surface of the substrate 206 and, in turn, resputter the respective target atoms onto the sidewalls of respective vias and trenches. Additional atoms can also be exhausted via the pressure control unit 218. In this way, improved seed layer coverage can be provided along the sidewalls of vias and trenches.

The microcontroller 222 can then implement an additional deposition phase in which the microcontroller turns off the RF generator 220 and activates the power supply 224 to provide a DC power to the target 208 via the electrode 210. The microcontroller 222 can also turn off the power supply 226 to decrease the deposition rate of the metal target atoms onto the substrate 206. The microcontroller 222 can control the system 200 to implement this additional (optional) deposition phase to deposit additional target material onto the substrate having a thickness that is about 10% that is applied during the initial deposition phase.

As an alternative example, the microcontroller 222 can be operative to implement simultaneous deposition and etching by activating the power supply 224 and 226 to bias the target 208 and the substrate 206, respectively, as well as by concurrently activating the RF and DC generator to energize the coil 214. The powers should be selected and controlled so that the deposition components of the process dominate the etching being implemented by energizing the coils 214. As a result, the deposition of the target material atoms onto the substrate facilitates coverage of the barrier layer, including along sidewalls of trenches and vias.

To ensure a proper seed layer formation, the coil 214 can be formed of the same material as the target 208 or an alloy of the target. For instance, if the target 208 is a substantially pure copper material, the coil 214 can be formed of a copper alloy, such as copper aluminum (CuAl) or copper tin (CuSn). Other high mobility materials that can be utilized for the coil include one or more of the materials selected from the group of copper, tantalum, copper, tantalum, iridium, ruthenium, and alloys thereof. For alloys thereof, such alloys can include one or more other materials in addition to the named materials.

What have been described above are examples of the present invention. It is, of course, not possible to describe every conceivable combination of components or methodologies for purposes of describing the present invention, but one of ordinary skill in the art will recognize that many further combinations and permutations of the present invention are possible. For example, while the FIGS. 2-5 illustrate an embodiment of the invention in conjunction with a dual damascene structure, those skilled in the art will understand and appreciated that the invention is equally applicable to single damascene and other structures. Accordingly, the present invention is intended to embrace all such alterations, modifications, and variations that fall within the spirit and scope of the appended claims.

What is claimed is:

1. A method to form a seed layer for an integrated circuit, the method comprising:
depositing a metal seed layer over a barrier layer such that the metal seed layer has a greater thickness along a top surface portion of at least one recessed feature formed in the substrate that is substantially coplanar with the substrate than a sidewall surface portion of the at least one recessed feature; and
etching a portion of the metal seed layer from the top surface portion of the at least one recessed feature to improve coverage of the metal seed layer along the sidewall surface portion of the at least one recessed feature and to mitigate overhang of the metal seed layer.

2. The method of claim 1, wherein the etching further comprises energizing a coil disposed about the substrate.

3. The method of claim 2, wherein the depositing further comprises sputtering atoms from a target material to form the metal seed layer.

4. The method of claim 3, wherein the coil comprises the same material as the target material or an alloy thereof.

5. The method of claim 2, wherein the target material comprises a copper material and the coil comprises a copper alloy material.

6. The method of claim 2, wherein the coil comprises a material selected from the group consisting essentially of copper, tantalum, iridium, ruthenium, and alloys thereof.

7. The method of claim 1, wherein the depositing further comprises sputtering atoms from a target material to form the metal seed layer by applying power to the target material and applying power to the substrate in an ionized environment within a processing chamber.

8. The method of claim 7, further comprising sputtering additional atoms from the target material after the etching.

9. The method of claim 8, wherein the sputtering of the additional atoms further comprises applying power to the substrate in the absence of applying power to the target material.

10. The method of claim 1, wherein the deposition and etching are performed separately.

11. A method for fabricating a copper seed layer over a barrier layer, the method comprising:
applying power to a copper target disposed above a substrate;
applying power to the substrate so that an electric field is created between the copper target and the substrate;
depositing copper atoms from the copper target onto exposed surfaces of the substrate, including within at least one of trenches and vias formed therein the substrate;
energizing a coil to generate a radio frequency field operative to redistribute portions of the deposited copper atoms onto sidewalls of at least one of trenches and vias.

12. The method of claim 11, further comprising depositing additional copper atoms from the target material after the portions of the deposited copper have been redistributed.

13. The method of claim 11, wherein the coil comprises a copper material or an alloy thereof.

14. The method of claim 11, further comprising applying DC power to the coil to deposit copper atoms from the coil onto the sidewalls of the at least one of trenches and vias.

15. A system for forming a seed layer on a substrate, comprising:
a metal target;
a first power source coupled to energize the target;
a chuck positioned below the target for supporting the substrate;
a coil disposed about a periphery of the chuck, and
a controller operative to control power applied to the metal target and to the substrate for depositing target atoms from the metal target on to exposed surfaces of the substrate, the controller further being operative to control energization of the coil to redistribute deposited target atoms to improve coverage of the seed layer on sidewalls of at least one of vias and trenches formed in the substrate.

16. The system of claim 15, wherein the coil comprises the same material as the target material or an alloy thereof.

17. The system of claim 16, wherein the target material comprises copper or titanium.

18. The system of claim 15, wherein the coil comprises a material selected from the group consisting essentially of copper, tantalum, iridium, ruthenium, titanium, and alloys thereof.

19. The system of claim 15, wherein the controller is programmed to control the first power source to supply power to the target and to control a second power source to supply power to the chuck during a first phase to deposit atoms from the target on exposed surfaces of the substrate with a first thickness, the controller controlling a radio frequency generator and a DC generator to energize the coil and controlling at least one of the first and second power sources to an off condition during a second phase to redistribute portions of the seed layer and thereby improve coverage of the seed layer on the sidewalls of the at least one of vias and trenches.

20. The system of claim 19, further comprising:
a pressure control unit operative to exhaust materials from an interior of the chamber; and
a gas source coupled to supply a gaseous medium for creating a charged plasma within the chamber, the controller controlling operation of the pressure control unit and the gas source.
